(19) United States
(12) Patent Application Publication
(10) Pub. No.: US 2026/0068570 A1
(43) Pub. Date: Mar. 5, 2026

(54) SEMICONDUCTOR DEVICE AND METHOD FOR MANUFACTURING SEMICONDUCTOR DEVICE

(71) Applicant: Renesas Electronics Corporation, Tokyo (JP)

(72) Inventor: Kodai OZAWA, Tokyo (JP)

(21) Appl. No.: 19/255,167

(22) Filed: Jun. 30, 2025

(30) Foreign Application Priority Data
Aug. 27, 2024 (JP) 2024-145046

(51) Int. Cl. H01L 21/3213; H01L 21/3205; H01L 21/66

(52) U.S. Cl. CPC H01L 21/32134

(57) ABSTRACT

A method of manufacturing a semiconductor device is provided, the method including: forming an insulating film on a semiconductor substrate; selectively removing the insulating film; forming a metal film on the semiconductor substrate by leaving a damage layer of a surface of the semiconductor substrate, the damage layer being generated when the insulating film is selectively removed; forming an electrode by selectively removing the metal film; and forming polyimide on the electrode. The damage layer of the surface of the semiconductor substrate, which is generated when the insulating film is selectively removed, may be selectively removed.

### CROSS-REFERENCE TO RELATED APPLICATIONS

The present application claims priority from Japanese Patent Application No. 2024-145046 filed on Aug. 27, 2024, the content of which is hereby incorporated by reference to this application.

### BACKGROUND

The present disclosure relates to a semiconductor device and a method of manufacturing the semiconductor device.

There is a disclosed technique listed below.
[Patent Document 1] Japanese Unexamined Patent Application Publication No. 2024-54039

Patent Document 1 discloses a method of manufacturing a semiconductor device, the method including being wet-etched in order to reduce damages to a surface of a semiconductor substrate due to dry etching in a contact step of connecting the semiconductor substrate and a metal wiring(s).

### SUMMARY

However, if the etching is performed for reducing the damages to the surface of the semiconductor substrate, there is a problem in which silicon pits are generated in a subsequent step(s). Therefore, a purpose of the present disclosure is to provide a manufacturing method and the like of a semiconductor device, the method forming a metal film by leaving a damage layer on the surface of the semiconductor substrate in order to suppress the generating of the silicon pits.

Other problems and novel features will be apparent from the present specification and the accompanying drawings.

According to one embodiment, a method of manufacturing a semiconductor device forms a metal layer on a semiconductor substrate by leaving a damage layer on a surface of the semiconductor substrate, the damage layer being generated when an interlayer insulating film is selectively removed.

According to the embodiment, the method of manufacturing the semiconductor device can be provided, the method forming the metal film by leaving the damage layer on the surface of the semiconductor substrate.

### BRIEF DESCRIPTION OF THE DRAWINGS

FIG. 1 is a top view of a first semiconductor device according to the present disclosures.

FIG. 2 is a VIB-VIB cross-sectional view of the semiconductor device of FIG. 1.

FIG. 3 is a first cross-sectional view of a semiconductor device, the first cross-sectional view explaining a manufacturing method of the related semiconductor device.

FIG. 4 is a second cross-sectional view of a semiconductor device, the second cross-sectional view explaining a manufacturing method of the related semiconductor device.

FIG. 5 is a third cross-sectional view of a semiconductor device, the third cross-sectional view explaining a manufacturing method of the related semiconductor device.

FIG. 6 is a fourth cross-sectional view of a semiconductor device, the fourth cross-sectional view explaining a manufacturing method of the related semiconductor device.

FIG. 7 is a fifth cross-sectional view of a semiconductor device, the fifth cross-sectional view explaining a manufacturing method of the related semiconductor device.

FIG. 8 shows VI characteristics when silicon pits of the semiconductor device are generated and VI characteristics when the silicon pits of the semiconductor device are not generated.

FIG. 9 is a schematic diagram of the silicon pits formed in the semiconductor device.

FIG. 10 is a flowchart of a manufacturing method of a related semiconductor device.

FIG. 11 is a cross-sectional view of a manufacturing method of a related semiconductor device.

FIG. 12 is a view showing a relationship between a light-etching time and VF characteristics.

FIG. 13 is a flowchart of a manufacturing method of a semiconductor device according to the present disclosure.

FIG. 14 is a cross-sectional view of a first manufacturing step of the semiconductor device according to the present disclosure.

FIG. 15 is a cross-sectional view of a second manufacturing step of the semiconductor device according to the present disclosure.

FIG. 16 is a cross-sectional view showing a generation principle of the silicon pits.

FIG. 17 is a view showing a relationship between a width and a depth of the silicon pit.

FIG. 18 is a view showing a path of a current when a probe is applied to a position at which the silicon pits are generated.

FIG. 19 is a view showing a path of a current when a bonding wire is applied to the position at which the silicon pits are generated.

FIG. 20 is a view showing consideration to an interval of the silicon pits.

FIG. 21 is a view showing a simulation result of a relationship between the interval of the silicon pits and VR characteristics.

FIG. 22 is a top view of a second semiconductor device according to the present disclosure.

FIG. 23 is an XXI-XXI cross-sectional view of the semiconductor device of FIG. 22.

### DETAILED DESCRIPTION

### Embodiment

Hereinafter, embodiments of the present invention will be explained with reference to the drawings. However, the invention according to the scope of patent claims is not limited to the below-mentioned embodiments. Also, all configurations explained in the embodiments are not necessarily essential as means for solving the problems. For clarifying the explanation, below-mentioned descriptions and drawings will be appropriately omitted and simplified. In each of the drawings, the same reference numerals are denoted to the same components, and duplicated explanation will be omitted if necessary.

### Explanation of Semiconductor Device of Present Disclosure

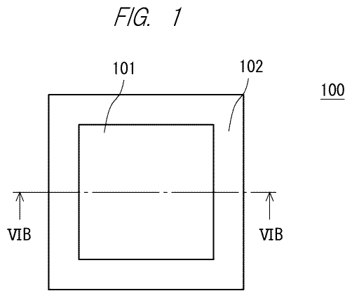

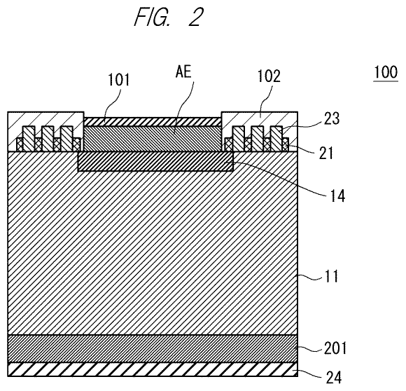

FIG. 1 is a top view of a first semiconductor device according to the present disclosures. FIG. 2 is a VIB-VIB cross-sectional view of the semiconductor device of FIG. 1. A first semiconductor device according to the present disclosure will be explained with reference to FIG. 1 and FIG. 2.

As shown in FIG. 1, the semiconductor device according to the present disclosure is formed into a rectangular shape when being viewed from an upper surface of a semiconductor substrate. In this example, although being formed into the rectangular shape, the semiconductor device may be formed into a rectangular having no corner, a circular, an overall, or the like so as to occupy a certain area of the semiconductor substrate. A semiconductor device 100 has an anode pad 101 at a center, and a polyimide 102 surrounding the anode pad when being viewed from the upper surface.

As shown in FIG. 2, the semiconductor device according to the present disclosure has a cathode electrode 24, an N⁺ type semiconductor region 201, an N⁻ type drift region 11, a P type body region 14, an interlayer insulating film 21, a metal layer 23, an anode electrode AE, the anode pad 101, and the polyimide 102 in order from bottom.

The semiconductor device according to the present disclosure is a diode forming an PN junction of a P⁺ type semiconductor region and the N⁻ type drift region. The semiconductor device may have no N⁺ type semiconductor region 201.

### Explanation of Manufacturing Method of Related Semiconductor Device

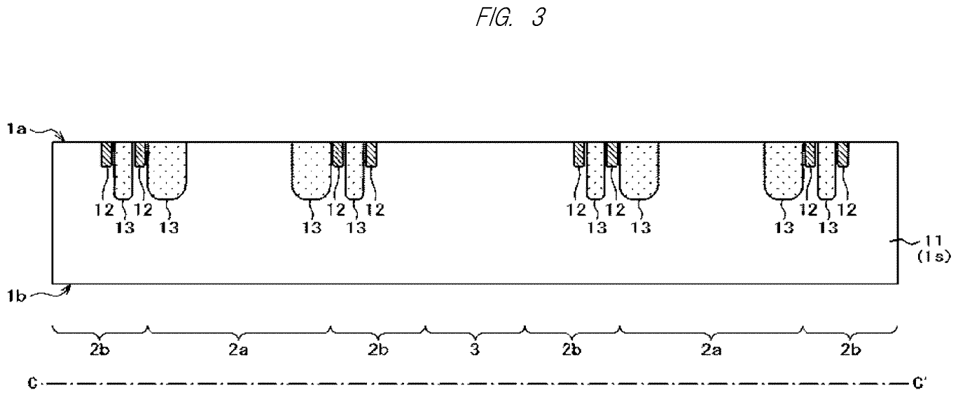

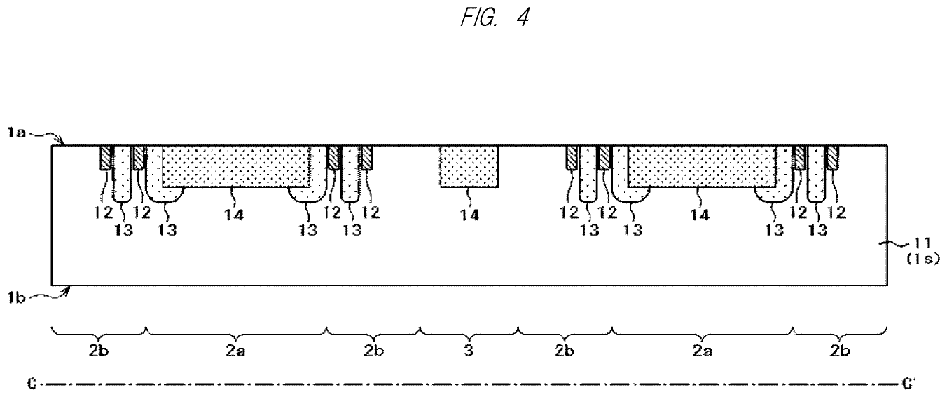

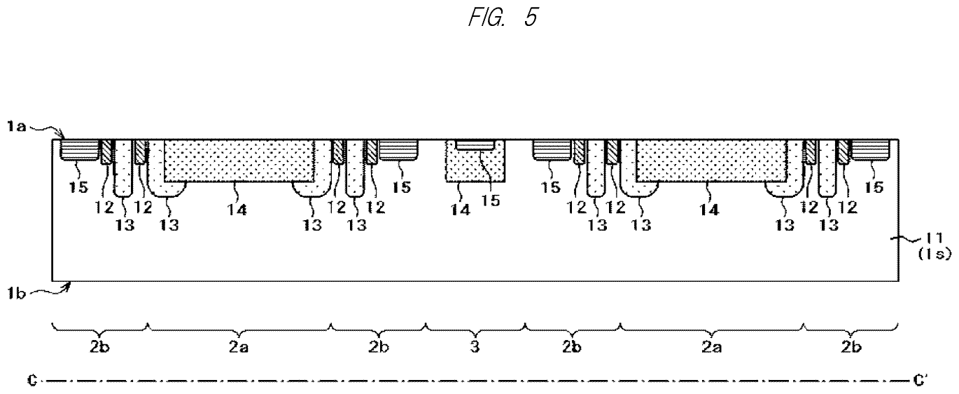

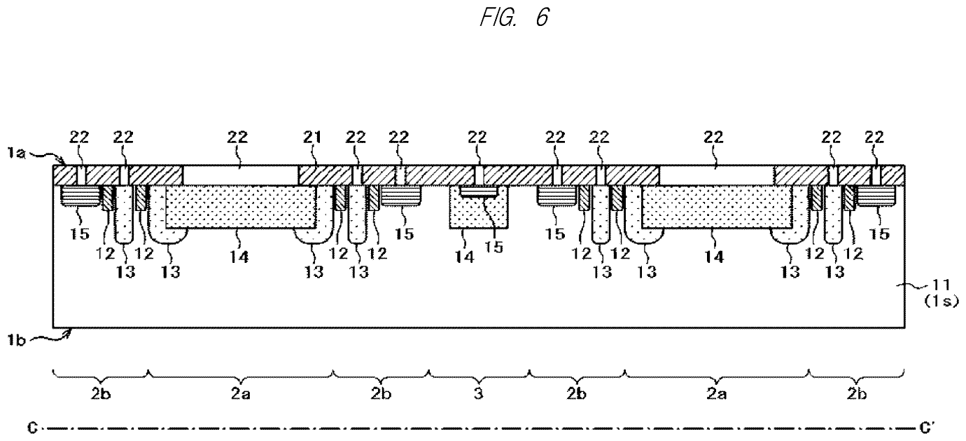

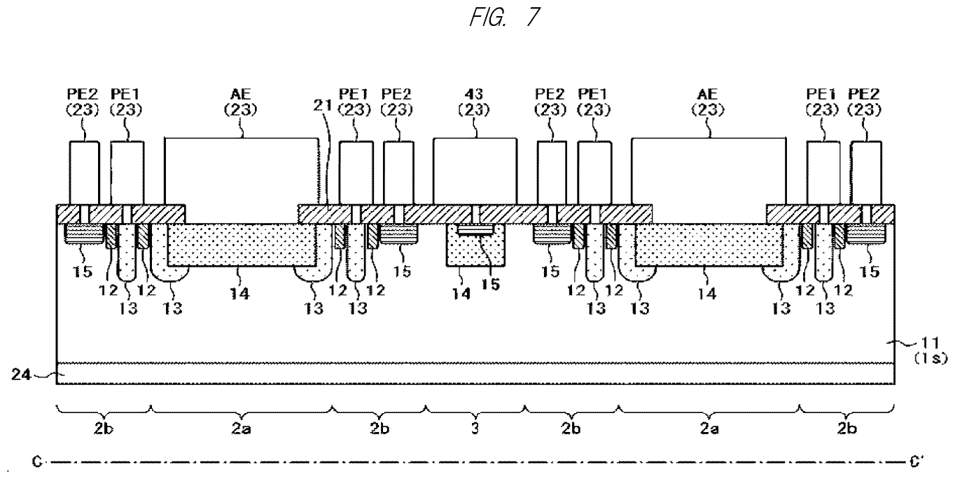

FIG. 3 is a first cross-sectional view of a semiconductor device, the first cross-sectional view explaining a manufacturing method of the related semiconductor device. FIG. 4 is a second cross-sectional view of a semiconductor device, the second cross-sectional view explaining a manufacturing method of the related semiconductor device. FIG. 5 is a third cross-sectional view of a semiconductor device, the third cross-sectional view explaining a manufacturing method of the related semiconductor device. FIG. 6 is a fourth cross-sectional view of a semiconductor device, the fourth cross-sectional view explaining a manufacturing method of the related semiconductor device. FIG. 7 is a fifth cross-sectional view of a semiconductor device, the fifth cross-sectional view explaining a manufacturing method of the related semiconductor device. A manufacturing method of a related semiconductor device according to the present disclosure will be explained with reference to FIG. 3 to FIG. 7. FIG. 3 to FIG. 7 show cross-sectional views showing manufacturing steps of the semiconductor device shown by FIG. 2.

Firstly, as shown in FIG. 3, a semiconductor wafer configured from a silicon monocrystalline semiconductor substrate 1a into which N type impurities such as phosphorus are introduced is prepared. The semiconductor wafer has an upper surface 1a and a back surface 1b opposite to the upper surface 1a.

An impurity concentration of the N type impurities in the semiconductor wafer can be set to, for example, about 2×10¹⁴ cm⁻³. A thickness of the semiconductor wafer can be set to, for example, about 450 micrometers to 1000 micrometers. Next, a silicon nitride film (Si₃N₄) is formed on the upper surface of the semiconductor wafer, and a Si₃N₄ film mask is formed by patterning the Si₃N₄ film. An element isolation region 12 is formed by oxidizing the upper surface of the semiconductor wafer in a region other than a Si₃N₄ film mask region under an oxidizing atmosphere.

Next, by an ion implantation method using a resist pattern as a mask, P type impurities are introduced into a semiconductor substrate 1s on an upper surface 1a side of the semiconductor wafer and, thereby, a P type field region 13 is formed. As an ion implantation condition at this time, the ion implantation condition in which, for example, an ion type is set as boron (B), a dose amount is set as about 3.5×10¹³ cm⁻², and ion implantation energy is set as about 75 keV can be exemplified as a suitable condition.

Next, after removing the resist, anneal at, for example, about 1200 degrees Celsius and about 30 minutes is performed under an atmosphere of nitrogen (N₂) gas as inert gas, and repair and drawing diffusion of crystal defects with respect to the P type field region 13 are performed.

Next, as shown in FIG. 4, by the ion implantation method using the resist pattern as a mask, the P type impurities are introduced into necessary portions of a cell region 2a and a scribe region 3 and, thereby, a P type body region 14 is formed.

Specifically, this P type body region 14 is formed on the P type field region 13 and on the N⁻ type drift region 11 (1s) that are formed in the cell region 2a. In addition, the P type body region 14 is formed on the N⁻ drift region 11 (1s) in the scribe region 3.

As the ion implantation condition at this time, the ion implantation condition in which, for example, the ion type is set as B, the dose amount is set as about 1×10¹³ cm^{Δ2}, and the implantation energy is set as about 75 keV can be exemplified as a suitable condition. After removing the resist, the anneal at, for example, about 1000 degrees Celsius and about 100 minutes is performed under the atmosphere of N₂ gas.

Next, as shown in FIG. 5, by the ion implantation method using the resist pattern as a mask, the N⁻ type impurities are introduced onto the N⁻ type drift region 11 (1s) in a peripheral region 2b and onto the P type body region 14 in the scribe region 3 and, thereby, an N⁺ type semiconductor region 15 is formed.

As the ion implantation condition at this time, the ion implantation condition in which, for example, the ion type is set as arsenic (As), the dose amount is set as about 5×10¹⁵ cm⁻², and the implantation energy is set as about 80 keV can be exemplified as a suitable condition. After removing the resist, the anneal at, for example, about 1000 degrees Celsius and about 100 minutes is performed under the atmosphere of N₂ gas.

Next, as shown in FIG. 6, an interlayer insulating film 21 made of, for example, a Phosphorous Silicate Glass (PSG) film is formed on the upper surface 1a of the semiconductor wafer by, for example, a CVD method or the like. The interlayer insulating film 21 is formed so as to cover, for example, the N⁻ type drift region 11 (1s), the P type field region 13, the P type body region 14, and the N⁺ type semiconductor region 15. A thickness of the interlayer insulating film 21 is, for example, about 0.6 micrometers. As a material of this interlayer insulating film 21, a Boro Phospho Silicate Glass (BPSG) film, a Non-doped Silicate Glass (NSG) film, a Spin-On-Glass (SOG) film, a silicon oxide (SiO₂) film, a composite film made of these, or the like can be exemplified as a suitable material.

Next, by an anisotropic dry etching method using the resist pattern as a mask, a contact hole (opening) 22 is formed in the interlayer insulating film 21. As gas of this anisotropic dry etching, mixed gas or the like made of, for example, argon (Ar) gas, torifluoromethane (CHF₃) gas, and tetrafluoromethane (CF₄) gas can be exemplified as suitable gas.

Subsequently, to reduce the damages to the upper surface of the semiconductor substrate due to the dry etching, the contact hole 22 and the semiconductor substrate 1s are etched by a SEZ wet etching method using the interlayer insulating film 21 as a mask after removing the resist. As etching liquid of the SEZ dry etching, for example, nitric acid (HNO₃):hydrogen fluoride (HF)=200:1 can be exemplified as suitable liquid. Or, by the dry etching method instead of the SEZ wet etching, the contact hole 22 and the semiconductor substrate 1s may be etched. As gas of this dry etching, for example, mixed gas made of oxygen (O₂) gas and tetrafluoromethane (CF₄) gas cab exemplified as suitable gas.

Next, as shown in FIG. 7, a metal layer 23 such as the anode electrode AE is formed. Specifically, for example, the following procedure will be done. Firstly, an aluminum-based metal film (for example, several % is silicon addition, the reminder is aluminum) is formed on the entire upper surface 1a of the semiconductor wafer by, for example, a spattering method so as to embed the contact hole 22. A thickness of the aluminum-based metal film is, for example, about 5 micrometers.

Next, by the dry etching method using the resist pattern as a mask, a metal layer 23 made of the aluminum-based metal film is formed. As gas of this dry etching, for example, chlorine (Cl₂) gas/boron trichloride (BCl₃) gas or the like can be exemplified as suitable gas.

Consequently, in the cell region 2a, the anode electrode AE is formed in the contact hole 22 and on the interlayer insulating film 21. In the scribe region 3, electrode pads 42, 43 are formed in the contact hole 22 and on the interlayer insulating film 21. Here, the metal layer 23 in the contact hole 22 is called a contact portion.

The anode electrode AE is electrically connected to the P type body region 14 formed in the cell region 2a. The electrode pad 42 is electrically connected to the P type body region 14 formed in the scribe region 3, and the electrode pad 43 is electrically connected to the N⁺ type semiconductor region 15 formed in the scribe region 3.

Next, an insulating film as a passivation film made of an organic film and the like that contain polyimide as a main component is formed on the anode electrode. A thickness of the insulating film is, for example, about 2.5 micrometers to 10 micrometers.

Next, by the dry etching method using the resist pattern as a mask, the insulating film is patterned, and an opening penetrating through the insulating film and reaching the anode electrode AE is formed. Then, an anode pad configured by the anode electrode AE in a portion exposed from the opening is formed.

Next, by performing a back grinding processing to the back surface 1b of the semiconductor wafer, for example, a thickness of about 800 micrometers is thinned to about 30 micrometers to 200 micrometers if necessary. For example, when a breakdown voltage is about 600 V, the final thickness is about 70 micrometers. In addition, if necessary, chemical etching and the like for removing the damages to the back surface 1b are also performed.

Next, for example by the spattering method, a cathode electrode 24 electrically connected to the N⁻ type drift region 11 (1s) is formed on the back surface 11b of the semiconductor wafer. Then, by dicing and the like, the semiconductor substrate 1s is divided into a semiconductor chip region(s) 2 and, by sealing it at a package if necessary, a semiconductor chip as the semiconductor device is almost completed.

### About Forming of Silicon Pits of Semiconductor Device

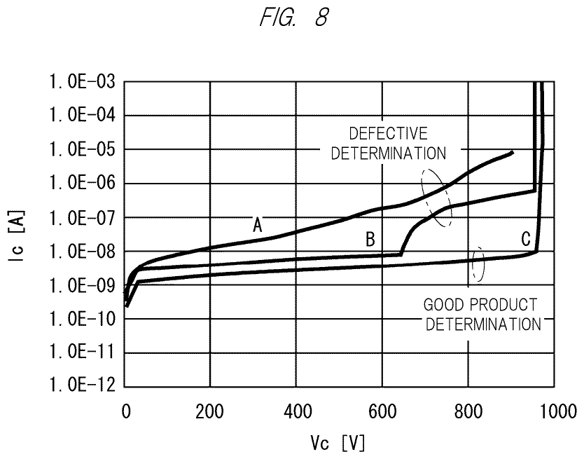

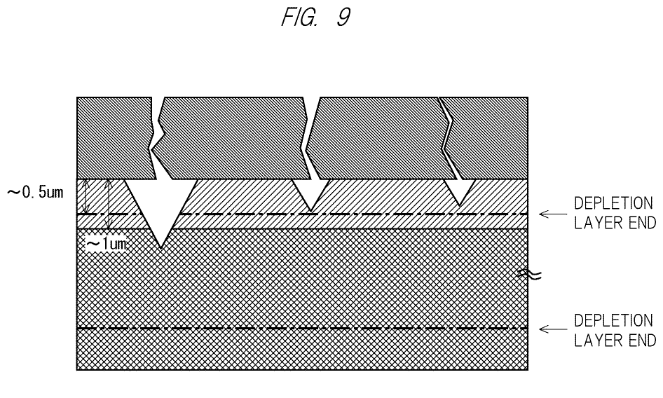

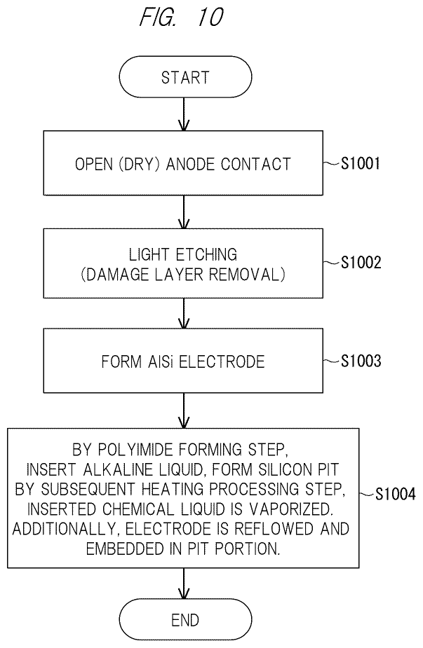

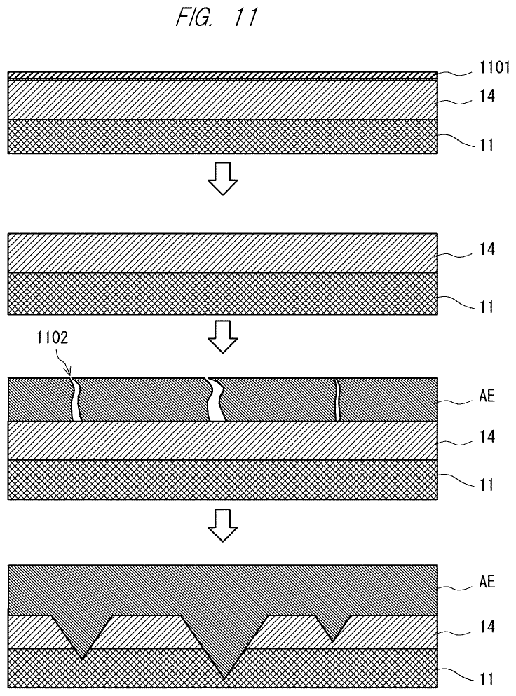

FIG. 8 shows VI characteristics when silicon pits of the semiconductor device are generated and VI characteristics when the silicon pits of the semiconductor device are not generated. FIG. 9 is a schematic diagram of the silicon pits formed on the semiconductor device. FIG. 10 is a flowchart of a manufacturing method of a related semiconductor device. FIG. 11 is a cross-sectional view of a manufacturing method of a related semiconductor device.

As shown in FIG. 8, in the related semiconductor device, when V1 characteristics are measured, a diode as a good product in which a current sharply rises at a certain voltage like C, and a diode as a defective product in which a current leaks and gradually rises like A and B have been manufactured. In the diode of the defective product, the silicon pits that open holes in silicon have been formed. Accordingly, A and B in which the silicon pits are generated are the defective products, and C is the good product.

As shown in FIG. 9, the silicon pits have also been formed in the good product, but the silicon pit has not reached a depletion layer. For example, when the depletion layer is 0.5 micrometers, the silicon pit of the good product is a depth of about 0.5 micrometers or less like a center or right, while the silicon pit of the defective product exceeds 0.5 micrometers and reaches 1 micrometer.

As shown in FIG. 10 and FIG. 11, it is conceivable that the silicon pits are generated as follows. Firstly, an anode contact is opened by the dry etching (Step S1001). The opening is formed by selectively removing the insulating film such as the interlayer insulating film on the semiconductor substrate. By doing so, as shown by a top figure in FIG. 11, a damage layer 1101 is formed on the P type body region 14 in the opening. The damage layer 1101 is an unterminated layer such as suboxide of silicon.

Next, the damage layer is removed by light etching (Step S1002). As shown by a second figure in FIG. 11, the damage layer 1101 is removed. Next, an AlSi electrode is formed (Step S1003). As shown by a third figure in FIG. 11, the anode electrode AE is formed by the AlSi. At this time, a trench 1102 reaching silicon may be formed.

Lastly, after forming the anode, the silicon pit is formed by inserting alkaline liquid into the trench 1102 by a polyimide forming step. Chemical liquid inserted in a subsequent heating processing step is vaporized. In addition to this, an electrode is reflowed and embedded in a silicon pit portion (Step S1004). As shown by a last figure in FIG. 11, the silicon pit reaches the N⁻ type drift region 11 and is formed.

It is conceivable that such a case is a factor of causing occurrence of a leak current. Therefore, the manufacturing method and the like of the semiconductor device in which the generating of the silicon pits is suppressed are required.

### Explanation of First Manufacturing Method of Semiconductor Device of Present Disclosure

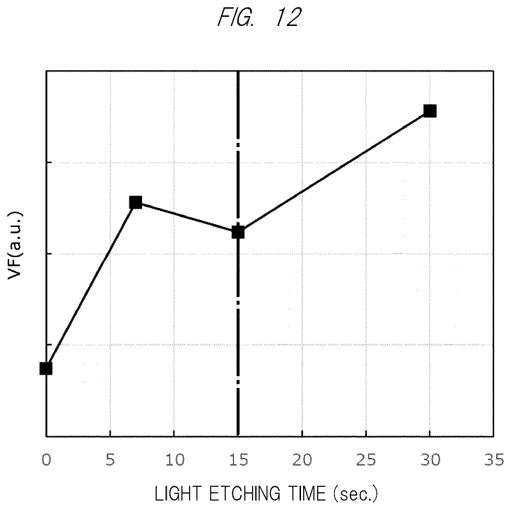

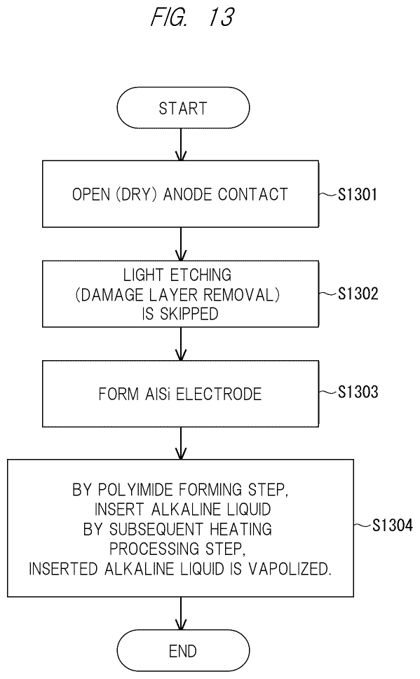

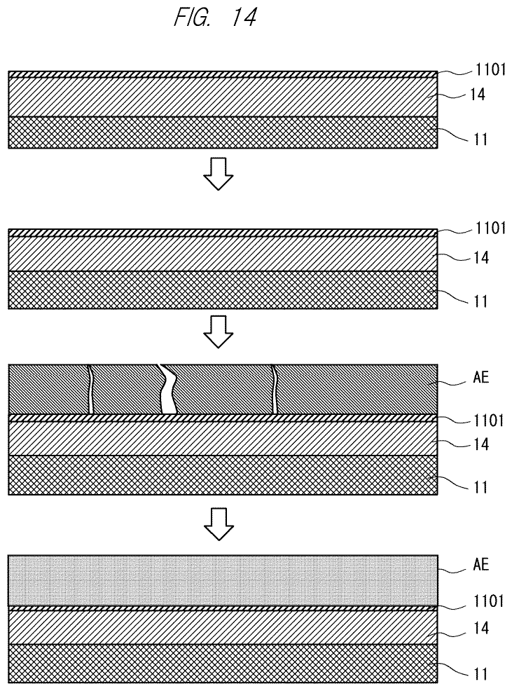

FIG. 12 is a view showing a relationship between a light-etching time and VF characteristics. FIG. 13 is a flowchart of a manufacturing method of a semiconductor device according to the present disclosure. FIG. 14 is a cross-sectional view of a first manufacturing step of the semiconductor device according to the present disclosure. A first manufacturing method of a semiconductor device according to the present disclosure will be explained with reference to FIG. 13 and FIG. 14.

The inventor has found out that when the damage layer is removed by Step S1002 in the manufacturing method of the related semiconductor device, the silicon pits are generated. In addition, the inventor has found that as shown by FIG. 12, for example by performing the light etching at 10 seconds to 20 seconds, VF characteristics as resistance can decrease, while unless the light etching is performed, the VF characteristics further decrease.

Therefore, as shown in FIG. 13, the first manufacturing method of the semiconductor device according to the present disclosure makes an anode contact open by the dry etching (Step S01301). As shown by a top figure in FIG. 14, the damage layer 1101 is formed by the anode opening. Next, the light etching for the removing the damage layer is skipped (Step S1302). As shown by a second figure in FIG. 14, the damage layer 1101 is left. Next, the AlSi electrode is formed (Step S1303). As shown by a third figure in FIG. 4, the anode electrode AE is formed.

Lastly, the alkaline liquid is inserted by the polyimide forming step, but the chemical liquid inserted by the subsequent heating processing step is vaporized (Step S1304). As shown by a last figure in FIG. 14, the silicon pits are not generated in the semiconductor device.

In this way, to suppress the generating of the silicon pits generated in forming the polyimide after forming the metal film, the manufacturing method of the semiconductor device in which the damage layer is left and the metal film is formed on the upper surface of the semiconductor substrate can be provided.

In addition, the semiconductor device manufactured in this way has the insulating film selectively arranged on the semiconductor substrate, the electrode formed by the metal film selectively arranged on the semiconductor substrate, and the polyimide on the electrode. Further, the semiconductor device has the damage layer under the electrode at a time of selectively removing the insulating film.

Explanation of Second Manufacturing Method of Semiconductor Device According to Present Disclosure

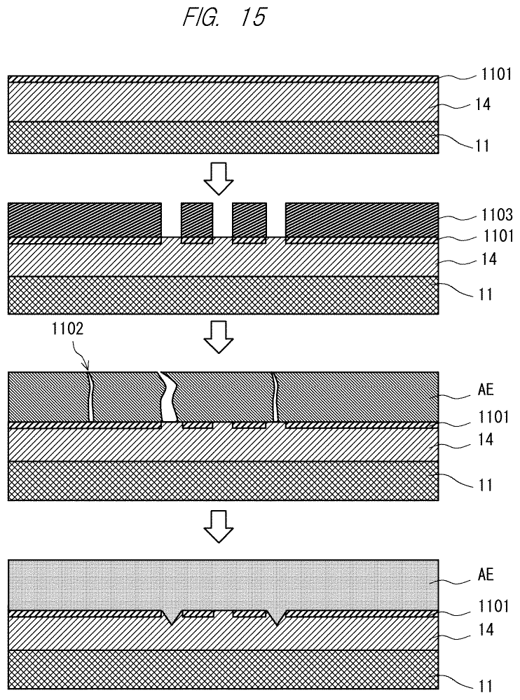

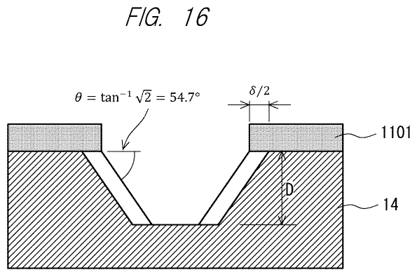

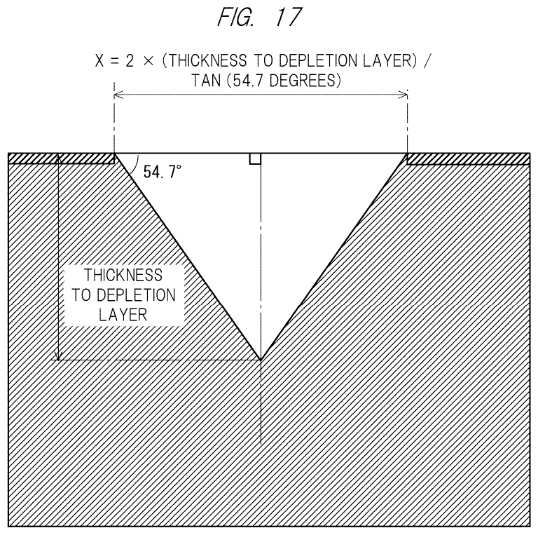

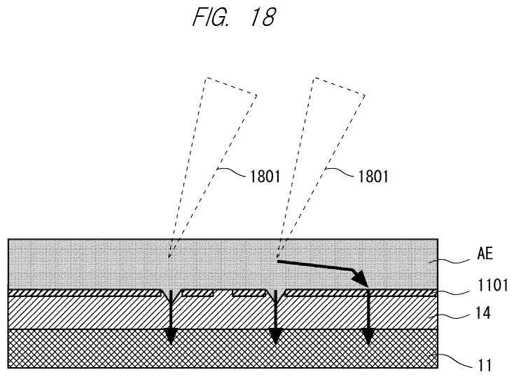

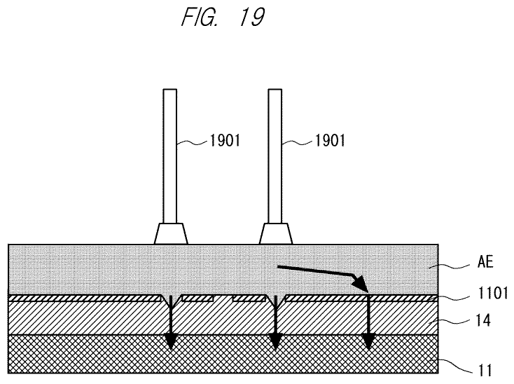

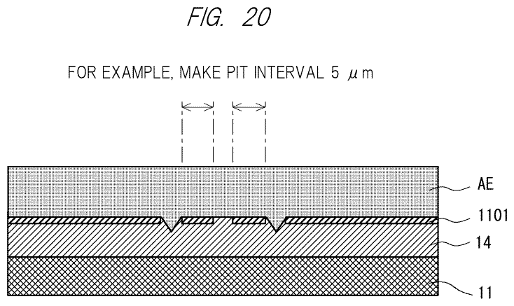

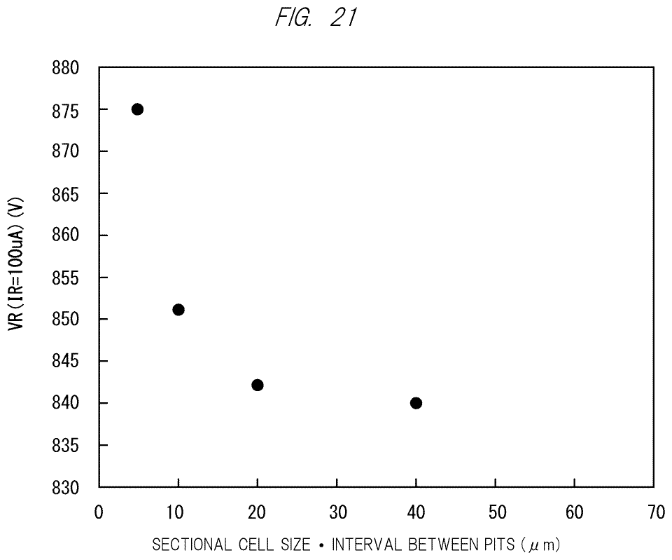

FIG. 15 is a cross-sectional view of a second manufacturing step of the semiconductor device according to the present disclosure. FIG. 16 is a cross-sectional view showing a generation principle of the silicon pits. FIG. 17 is a view showing a relationship between a width and a depth of the silicon pit. FIG. 18 is a view showing a path of a current when a probe is applied to a position at which the silicon pits are generated. FIG. 19 is a view showing a path of a current when a bonding wire is applied to the position at which the silicon pits are generated. FIG. 20 is a view showing consideration to an interval of the silicon pits. FIG. 21 is a view showing a simulation result of a relationship between the interval of the silicon pits and VR characteristics. A second manufacturing method of the semiconductor device according to the present disclosure will be explained with reference to FIG. 15 to FIG. 21.

The second manufacturing method of the semiconductor device according the present disclosure is to control the generating of the silicon pits. As shown by a top figure in FIG. 15, the damage layer 1101 is formed in the opening for an anode electrode contact. Next, as shown by a second figure in FIG. 15, the damage layer 1101 is selectively removed by forming a mask 1103. A time of the light etching at this time is preferably 10 seconds to 20 seconds.

Next, as shown by a third figure in FIG. 15, the anode electrode AE is formed. At this time, the trench 1102 reaching silicon is formed in the anode electrode AE. Next, as shown by a last figure in FIG. 15, after forming the polyimide, the silicon pits are formed by reflowing the anode electrode AE. However, the silicon pits are not formed in a portion in which the damage layer is not removed, and a place of the silicon pit is also selectively formed.

By selectively removing the damage layer in this way, the manufacturing method of the semiconductor device, in which the generating of the silicon pits is controlled, and the semiconductor device formed so are obtained.

FIG. 16 shows the etching of silicon due to the insertion of the alkaline liquid. As shown by FIG. 16, when the opening of the damage layer exists, the P type body region 14 is etched so as to form an angle of tan⁻¹√2 =54.7 degrees (tan⁻¹(2)^{1/2}=54.7 degrees) to the upper surface. This is because if it is assumed that the upper surface is a plane orientation of {100}, its side surface is a plane orientation of {111}. If it is assumed that its depth is D, D is indicated by D=(magnitude X of opening) multiplied by tan(54.7 degrees)/2 as shown by FIG. 17. If the magnitude X that removes the damage layer is 2 multiplied by (thickness to depletion)/tan(54.7 degrees), the silicon pit never reaches the depletion layer.

Therefore, a region in which the damage layer is removed is preferably smaller than (thickness of depletion layer of semiconductor device) multiplied by 2/tan(54.7 degrees). For example, if the depletion layer is generated from 500 nm, the region in which the damage layer is removed preferably has a width of 708 nm. In this way, by controlling the width for removing the damage layer, the depth of the silicon pit can be controlled.

As shown in FIG. 18, a probe 1801 for a wafer test may be placed in a region in which the silicon pits are generated. As shown in FIG. 12, due to the VF characteristics, a current more easily flows at an etching time of 0, while if the light etching is performed, the current becomes difficult to flow. Thus, by placing the probe 1801 in the region in which the selectively formed silicon pits formed are generated, a current concentration due to the probe 1801 can be prevented. Therefore, the region in which the damage layer is selectively removed is preferably suitable to be combined with a region of placing the probe 1801.

As shown in FIG. 19, a bonding wire 1901 may be placed in the region in which the silicon pits are generated. By placing the boding wire 1901 in the region in which the selectively formed silicon pits are generated, a current concentration due to the bonding wire 1901 can be prevented similarly to the probe 1801. Therefore, the region in which the damage layer 1101 is selectively removed is preferably suitable to be combined with the region of placing the bonding wire 1901.

A pit interval will be considered with reference to FIG. 20 and FIG. 21. As shown in FIG. 20 and FIG. 21, when simulation is performed by changing a pit interval, the pit interval becomes an avalanche point due to an electric field concentration at a tip of the silicon pit and a decrease in a breakdown voltage depending on a pit shape can be seen. As shown in FIG. 21, it can be understood from the simulation that VR characteristics which are breakdown voltage characteristics rise when the pit interval is 10 micrometers or less, for example, at 5 micrometers. Narrowing the pit interval makes it possible to obtain a field plate effect, relieve an electric field at the pit tip, and improve the breakdown voltage characteristics. Therefore, as shown in FIG. 20, by selectively removing the damage layer, the pit interval is 10 micrometers or less, preferably 5 micrometers or less.

### Explanation of Second Semiconductor Device According to Present Disclosure

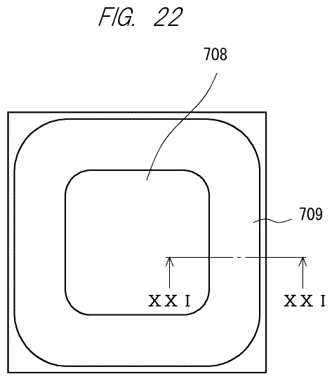

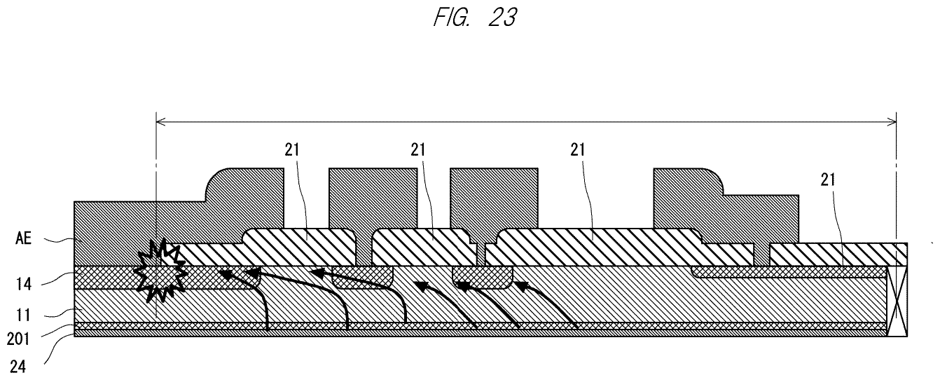

FIG. 22 is a top view of a second semiconductor device according to the present disclosure. FIG. 23 is an XXI-XXI cross-sectional view of the semiconductor device of FIG. 22. A second semiconductor device according to the present disclosure will be explained with reference to FIG. 22 and FIG. 23.

As shown in FIG. 22 and FIG. 23, near an end portion of the anode electrode AE, carries flow from a peripheral configuration at a time of a recovering operation, so that the current concentration more easily occurs than the anode electrode AE. Therefore, to prevent the current concentration from occurring, a light etching processing is performed near the end portion of the anode electrode AE. That is, the end portion of the anode electrode AE is combined with the region in which the damage layer 1101 is removed. By doing so, destruction during the recovering operation is suppressed. The “near the end portion” is, for example, a range of about 5 micrometers to 100 micrometers from the end portion.

For example, the semiconductor device according to the above embodiment may have a configuration in which a conductive type (p type or n type) of the semiconductor substrate, the semiconductor layer, the diffusion layer (diffusion region), and the like is reversed. Therefore, when one conductive type of an n type and a p type is a first conductive type and the other conductive type is a second conductive type, this makes it possible to set the first conductive type to the p type and set the second conductive type to the n type and, on the contrary, and also makes it possible to set the first conductive type to the n type and to set the second conductive type to the p type on the contrary. As described above, the invention made by the present inventor has been specifically explained based on the embodiment, but the present invention is not limited to the above-mentioned embodiment and, needless to say, can variably modified within a range of not departing from the gist thereof.

What is claimed is:

1. A method of manufacturing a semiconductor device, the method comprising:
forming an insulating film on a semiconductor substrate;
selectively removing the insulating film;
forming a metal film on the semiconductor substrate by leaving a damage layer of a surface of the semiconductor substrate, the damage layer being generated when the insulating film is selectively removed;
forming an electrode by selectively removing the metal film; and
forming polyimide on the electrode.

2. The method according to claim 1,
wherein the damage layer of the surface of the semiconductor substrate, which is generated when the insulating film is selectively removed, is selectively removed.

3. The method according to claim 2,
wherein a region in which the damage layer is removed is smaller than (a thickness of a depletion layer of the semiconductor device) multiplied by 2/tan(54.7 degrees).

4. The method according to claim 2,
wherein removal of the damage layer is performed by performing wet etching during 10 seconds to 20 seconds.

5. The method according to claim 2,
wherein a probe or a bonding wire for a wafer test is placed in a region in which the damage layer is removed.

6. The method according to claim 2,
wherein an interval of a region in which the damage layer is removed is 5 micrometers or less.

7. The method according to claim 2,
wherein a region in which the damage layer is removed is near an end portion of the electrode.

8. A semiconductor device comprising:
an insulating film selectively arranged on a semiconductor substrate;
an electrode formed by a metal film selectively arranged on the semiconductor substrate; and
polyimide on the electrode,
wherein the semiconductor device has a damage layer under the electrode in selectively removing the insulating film.

9. The semiconductor device according to claim 8,
wherein the damage layer is selectively removed.

10. The semiconductor device according to claim 9,
wherein a region in which the damage layer is removed smaller than (a thickness of a depletion layer of the semiconductor device) multiplied by 2/tan(54.7 degrees).

11. The semiconductor device according to claim 9,
wherein a probe or a bonding wire for a wafer test is placed in a region in which the damage layer is removed.

12. The semiconductor device according to claim 9,
wherein an interval of a region in which the damage layer is removed is 5 micrometers or less.

13. The semiconductor device according to claim 9,
wherein a region in which the damage layer is removed is near an end portion of the electrode.
